(19) United States
(12) Patent Application Publication
(10) Pub. No.: US 2018/0268989 A1
(43) Pub. Date: Sep. 20, 2018

(54) POWER RECEIVER COIL IN WIRELESS CHARGING SYSTEM

(71) Applicant: Shenzhen Yichong Wireless Power Technology Co. Ltd., Shenzhen (CN)

(72) Inventors: Tun LI, San Jose, CA (US); Dawei HE, Burlingame, CA (US); Siming PAN, San Jose, CA (US); Yihong DAI, Campbell, CA (US)

(21) Appl. No.: 15/800,135

(22) Filed: Nov. 1, 2017

Related U.S. Application Data
(60) Provisional application No. 62/472,348, filed on Mar. 16, 2017.

(51) Int. Cl. H01F 27/28; H02J 7/02; H02J 50/10; H05K 1/02; H05K 1/16

(52) U.S. Cl. CPC H01F 27/2804; H02J 7/025; H05K 1/165; H05K 1/028; H02J 50/10

(57) ABSTRACT

A design of a power receiver coil for a wireless charging system is disclosed. The power receiver coil may include a magnetic coil, two terminals and a base. The terminals may extend from the magnetic coil and the magnetic coil may be placed on the base. The wire of the magnetic coil may be uniformly spaced between adjacent turns.

### CROSS-REFERENCE TO RELATED APPLICATIONS

This application claims the benefit of U.S. Provisional Application Ser. No. 62/472,348, filed Mar. 16, 2017, and entitled “POWER RECEIVER COIL IN WIRELESS CHARGING SYSTEM”. The entirety of the aforementioned application is incorporated herein by reference.

### TECHNICAL FIELD

The disclosure relates generally to a wireless charging system, particularly, to a design of a power receiver coil in the system.

### BACKGROUND

Wireless charging is an evolving technology that may bring a new level of convenience of charging electronic devices. In a wireless charging system, particularly an inductive wireless charging system, energy is transferred from one or more power transmitter (TX) coils to one or more power receiver (RX) coils through magnetic coupling.

In a general wireless charging system, the input power is delivered from a power transmitter to a power receiver through two or more coupled magnetic coils. The coupled magnetic coils include the power transmitter coils and power receiver coils. Conventional wireless charging systems usually have a very limited charging area and require a RX device be aligned with a TX device while charging.

To improve user experiences and broaden wireless charging applications, it is desirable to design a wireless charging system to cover a large charging area with a high charging efficiency. This disclosure proposes a design of a RX coil to achieve a large uniform charging area with a high charging efficiency in a wireless charging system.

### SUMMARY

The present disclosure is directed to a power receiver coil for a wireless charging system. The power receiver coil may include a magnetic coil, two terminals and a base. The terminals may extend from the magnetic coil and the magnetic coil is placed on the base. The wire of the magnetic coil is uniformly spaced between adjacent turns.

Another aspect of this disclosure is directed to a wireless charging system. The system may include a power transmitter and a power receiver. The power transmitter may include one or more power transmitter coils. The power transmitter coils may be coupled to one or more power receiver coils. The power receiver may include the one or more power receiver coils, and may be configured to wirelessly charge a device. Each of the one or more power receiver coils may include a wire, two terminals and a base. The wire may be routed into each of the one or more power receiver coils. The wire of the magnetic coil may be uniformly spaced between adjacent turns. The two terminals may extend from each of the one or more power receiver coils, and each power receiver coil may be placed on the base.

It is to be understood that the foregoing general description and the following detailed description are exemplary and explanatory only, and are not restrictive of the invention, as claimed.

### BRIEF DESCRIPTION OF THE DRAWINGS

The accompanying drawings, which constitute a part of this disclosure, illustrate several non-limiting embodiments and, together with the description, serve to explain the disclosed principles.

FIG. 1 is a block diagram illustrating a wireless charging system, consistent with exemplary embodiments of the present disclosure.

FIG. 2 is a graphical representation illustrating an overview of a power receiver coil, consistent with exemplary embodiments of the present disclosure.

FIGS. 3(a)-3(b) are graphical representations illustrating a top view of a power receiver coil, consistent with exemplary embodiments of the present disclosure.

FIGS. 4(a)-4(b) are graphical representations illustrating a side view of a power receiver coil, consistent with exemplary embodiments of the present disclosure.

### DETAILED DESCRIPTION OF THE EMBODIMENTS

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments consistent with the present invention do not represent all implementations consistent with the invention. Instead, they are merely examples of systems and methods consistent with aspects related to the invention.

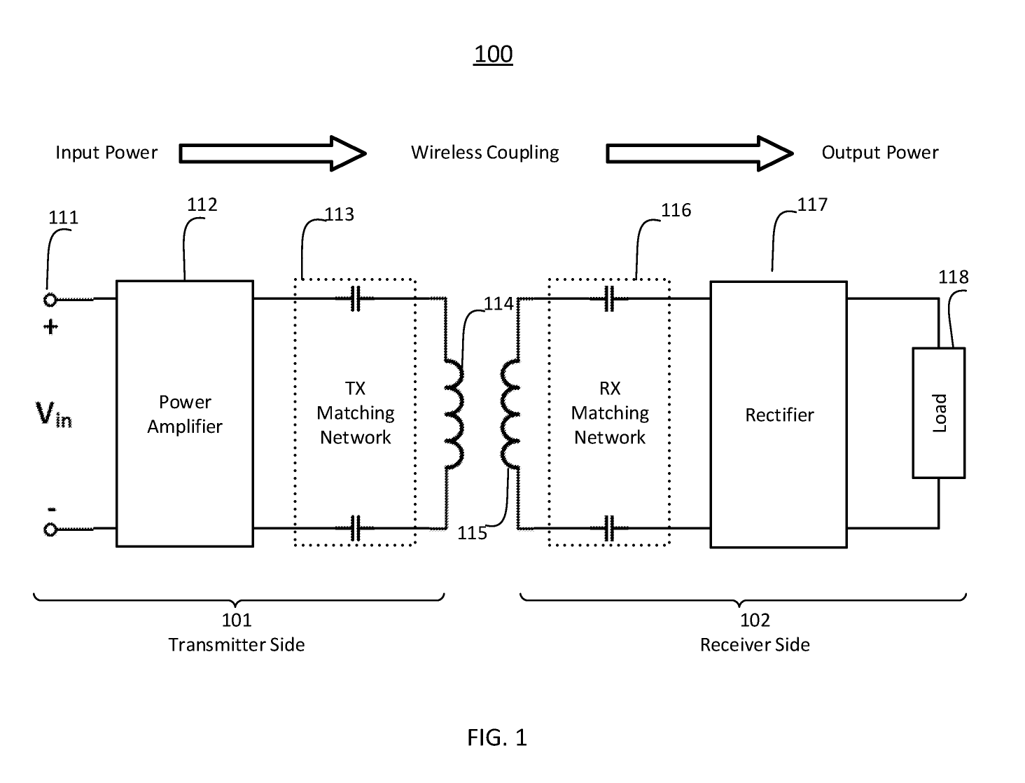

FIG. 1 is a block diagram illustrating a wireless charging system 100, consistent with exemplary embodiments of the present disclosure. The system 100 may comprise a number of components, some of which may be optional. In some embodiments, the system 100 may include many more components than those shown in FIG. 1. However, it is not necessary that all of these components be shown in order to disclose an illustrative embodiment.

The system 100 may include a transmitter side 101 and a receiver side 102. The transmitter side 101 may include power input nodes (+ and −) 111, a power amplifier 112, and a power transmitter. The power transmitter may include a TX matching network 113, and one or more TX coils 114. The receiver side 102 may include a power receiver, a rectifier 117, and a load 118 of a RX device. The power receiver may include one or more RX coils 115 and a RX matching network 116. The load 118 can be a battery of a device to be charged. The device can be a mobile device, a wearable device, a tablet device, a computer, a car, or any device that includes a chargeable battery. The one or more RX coils can be coupled to the device. The power input nodes 111 may be coupled to the power amplifier 112. The power amplifier 112 may be coupled to the TX matching network 113. The TX matching network 113 may be coupled to one or more TX coils 114. The TX matching network 113 may include one or more capacitors. Capacitance of one or more of the capacitors may be adjustable. The TX matching network 113 and the TX coil(s) 114 may form a resonant circuit or an LC circuit where the L represents the TX coil(s) and C represents the capacitor connected together. The frequency of the LC circuit can be adjusted by adjusting the capacitance of the TX matching network 113. The TX coil(s) 114 may be coupled with one or more RX coils 115 via magnetic coupling. In the receiver side 102, the RX coil(s) 115 may be coupled to the RX matching network 116, the RX matching network 116 may be coupled to the rectifier 117, and the rectifier 117 may be coupled to the load 118. The RX matching network 116 may include one or more capacitors. One or more capacitors may have adjustable capacitance. The capacitors may be used to adjust the frequency of an LC circuit formed by the RX coil(s) 115 and the RX matching network 116 to work with the LC circuit on the transmitter side 101. Accordingly, the resonant frequency of the LC circuit can be determined by tuning the capacitance of the capacitors. The TX matching network 113, TX coil(s) 114, RX coil(s) 115 and RX matching network 116 form a coil-to-coil sub-system 103.

In one embodiment, an input voltage is converted from a DC power to an AC power and amplified by the power amplifier 112. Then the power is transmitted from the transmitter side 101 to the receiver side 102 through two or more coupled magnetic coils. The AC voltage received at the receiver side 102 is regulated back to a DC voltage by the rectifier 117 and then delivered to the load 118.

An RX coil can be designed to achieve a large effective charging area while minimizing the physical dimensions of the magnetic coil by optimizing its parameters. The effective charging area of a set of a TX coil and an RX coil refers to a charging area, where if the center of the RX coil is placed inside of the area, a coil-to-coil efficiency between the TX coil and the RX coil should be no less than a desired value (e.g., a value desired or pre-determined by a user). The effective charging area may be on a horizontal plane that is parallel to the TX coil. For example, the effective charging area may be on the same plane as the TX coil. “Horizontal” may refer to a direction that is parallel to the plane of a TX or RX coil, while “vertical” may refer to a direction that is perpendicular to the plane. A radius of the effective charging area may be defined as the horizontal distance between the center of a TX coil (e.g., a vertical projection of the center on the horizontal plane where the effective charging area resides) and the boundary of the effective charging area. In some embodiments, the vertical distance between the TX and RX coils may vary from 0-7 mm. The parameters of an RX coil may refer to a coil shape, turn number, outer diameter, inner diameter, etc. Based on simulations and experiments, these parameters can be tuned to optimize the coil-to-coil efficiency. The coil-to-coil efficiency refers to the efficiency between a TX coil and an RX coil. It is calculated by the ratio of the output power of the RX coil over the input power of the TX coil. The loss that affects the coil-to-coil efficiency includes the coil-to-coil loss and the parasitic resistance loss of the TX and RX matching capacitors.

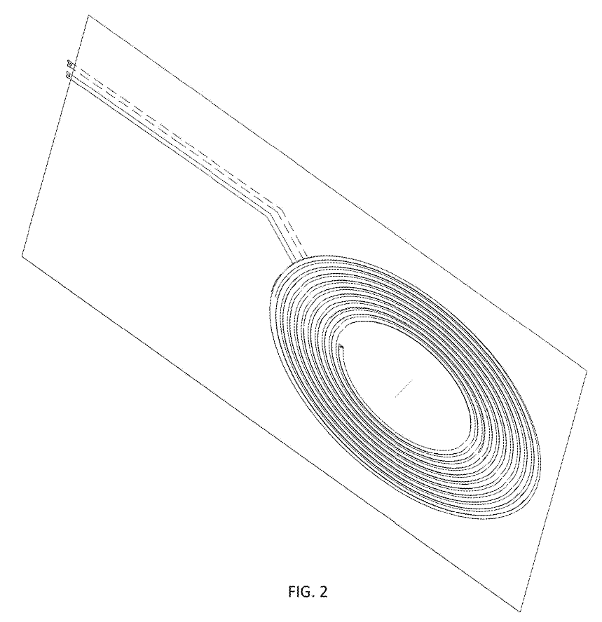

Values of the parameters for an exemplary RX coil design are presented in Table 1. Small variations of the values should be considered as within the scope of the structure and design in this disclosure. Potential variation ranges are also presented in Table 1. The number of turns in the magnetic coil may be 12. The magnetic coil may have a circular or slightly elliptical shape with an outer diameter of 50 mm and an inner diameter of 25 mm. The edge-to-edge spacing between adjacent turns of the magnetic coil may be 0.4 mm. The coil type may be an FPCB. The magnetic coil may be placed on a dielectric sheet, which is made of a polyimide (PI) dielectric material with a dielectric thickness of 0.025 mm. In some embodiments, the magnetic coil may be printed on the dielectric sheet. The wire may be made of copper with a trace thickness of 2 oz. (0.0696 mm). This particular RX coil design can achieve a uniform effective charging area with no less than 90% of coil-to-coil efficiency, when paired with an A11 type TX coil in WPC (Wireless Power Consortium) specification reference design, within a circular effective charging area, which has a radius of no less than 20 mm. An overview of the exemplary RX design is shown in FIG. 2.

TABLE 1

| Parameter | Symbol | Value | | Variation Range | |
|---|---|---|---|---|---|
| Turn Number | N | 12 | | ±1 | |
| Coil Shape | / | Circle | | Slightly Elliptical | |
| Outer Diameter | OD | 50 | mm | ±2 | mm |
| Inner Diameter | ID | 25 | mm | ±2 | mm |
| Space between Turns | S | 0.4 | mm | ±0.1 | mm |
| Coil Type | / | FPCB | | / | |
| Dielectric Material | / | Polyimide | | Similar Dielectric | |
| | | (PI) | | | |
| Dielectric Thickness | H | 0.025 | mm | Arbitrary Value | |
| Trace Material | / | Copper | | Similar Material | |
| Trace Thickness | D | 2 | oz. | ±0.5 | oz. |
| | | (0.0696 | mm) | | |
| Trace Width | W | 0.675 | mm | ±0.16 | mm |

In some embodiment, the RX coil may have an outer diameter of 48-52 mm and an inner diameter of 23-27 mm. The RX coil may include 11-13 turns of wire. The wire of the magnetic coil may be uniformly spaced between adjacent turns with an edge-to-edge spacing of 0.3-0.5 mm. The wire may be made of copper, and has a trace thickness of 1.5-2.5 oz. and a trace width of 0.515-0.835 mm.

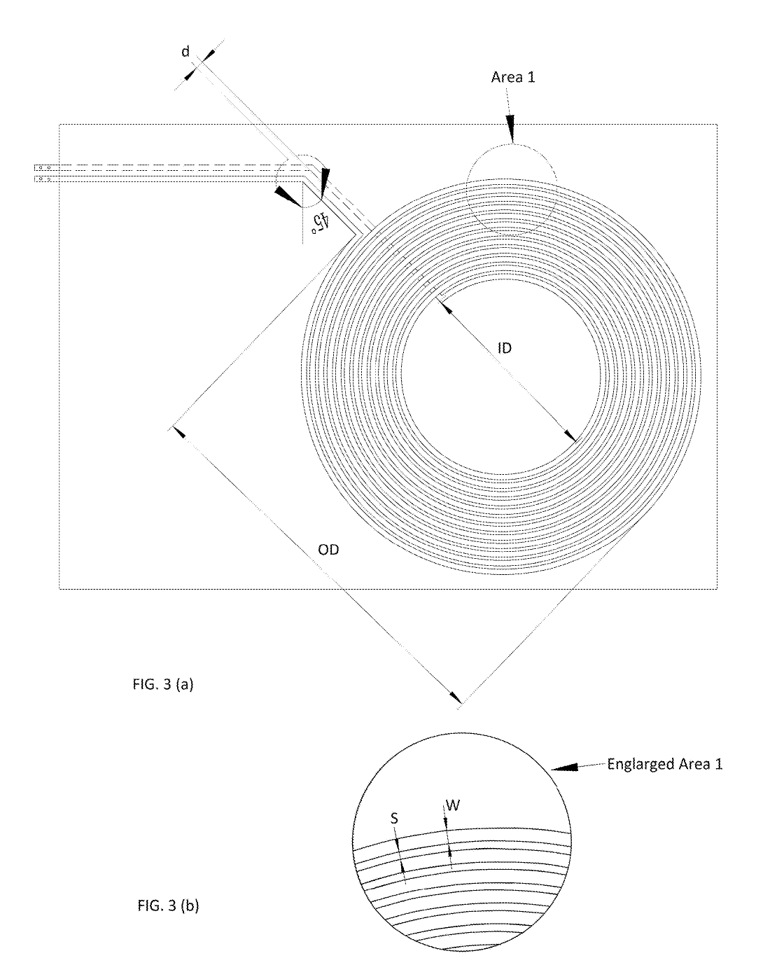

FIG. 3(a) is a graphical representation illustrating a top view of an exemplary RX coil. As shown in FIG. 3(a), the wire is routed into a circular shaped coil, with two extending terminals, and the magnetic coil is printed on a base. In some embodiments, the base may be a dielectric sheet/layer, which may be made of polyimide (PI). The inner diameter of the magnetic coil is denoted as ID and the outer diameter of the magnetic coil is denoted as OD. The two terminals are separated with an edge-to-edge distance of d (e.g., 1 mm). In some embodiments, the two terminals are bent into an angle of 45° as shown in FIG. 3(a). To have a clear view of the RX coil, Area 1 is selected and enlarged in FIG. 3(b). In one embodiment, the wire has a trace width of W, and an edge-to-edge spacing of S between the adjacent turns in the magnetic coil. In this exemplary design, the RX coil contains 12 turns of wire.

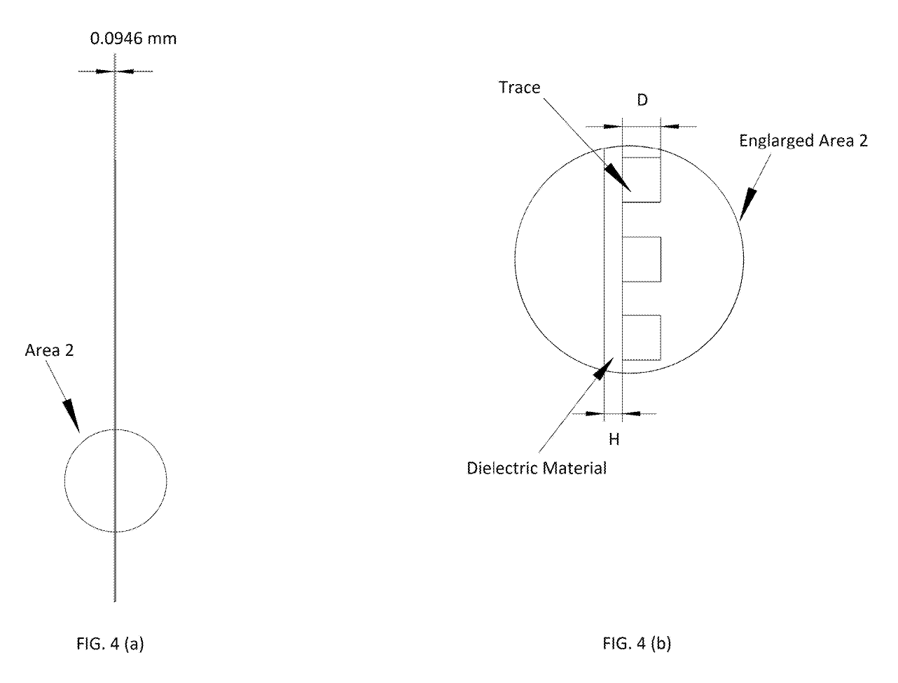

FIG. 4(a) is a graphical representation illustrating a side view of an exemplary RX coil. The thin rod-like shape illustrates the side view of the RX coil and the sheet of the dielectric material. As shown in FIG. 4(a), the thickness of the RX coil is 0.0946 mm, which is the summation of the dielectric thickness H and the trace thickness D (without considering the thickness of terminals). This is resulted from the design that the wire is routed into a coil in the same plane, and the magnetic coil is printed on the sheet of the dielectric material. To have a clear view of the location of the magnetic coil, Area 2 is selected and enlarged in FIG. 4(b). Three rectangles represent the cross-sections of the exemplary wire, which has a trace height/thickness of D. As shown in FIG. 4 (b), the wire locates closely contacting with the sheet of the dielectric material that has a thickness of H.

The invention described and claimed herein is not to be limited in scope by the specific preferred embodiments disclosed herein, as these embodiments are intended as illustrations of several aspects of the invention. Indeed, various modifications of the invention in addition to those shown and described herein will become apparent to those skilled in the art from the foregoing description. Such modifications are also intended to fall within the scope of the appended claims.

What is claimed is:

1. A power receiver coil for a wireless charging system, comprising:
a magnetic coil routed by a wire in a plane, wherein the wire of the magnetic coil is uniformly spaced between adjacent turns;
two terminals extending from the magnetic coil; and
a base on which the magnetic coil is placed.

2. The power receiver coil of claim 1, wherein a coil type includes a flexible printed circuit board.

3. The power receiver coil of claim 1, wherein the magnetic coil has a circular shape.

4. The power receiver coil of claim 1, wherein the magnetic coil has an outer diameter of 48-52 mm.

5. The power receiver coil of claim 1, wherein the magnetic coil has an inner diameter of 23-27 mm.

6. The power receiver coil of claim 1, wherein the magnetic coil has 11-13 turns.

7. The power receiver coil of claim 1, wherein the wire of the magnetic coil is uniformly spaced between adjacent turns with an edge-to-edge spacing of 0.3-0.5 mm.

8. The power receiver coil of claim 1, wherein the wire is made of copper, and has a trace thickness of 1.5-2.5 oz. and a trace width of 0.515-0.835 mm.

9. The power receiver coil of claim 1, wherein the two terminals are separated with an edge-to-edge distance of 1 mm.

10. The power receiver coil of claim 1, wherein the two terminals are bent to form an angle of 45°.

11. The power receive coil of claim 1, wherein the base is a dielectric material.

12. The power receiver coil of claim 1, wherein the base is made of polyimide, and has a thickness of 0.025 mm.

13. A wireless charging system, comprising:
a power transmitter configured to receive an input power, the power transmitter comprising one or more power transmitter coils wirelessly coupled to one or more power receiver coils; and
a power receiver comprising the one or more power receiver coils and configured to charge a device,
wherein each of the one or more power receiver coils includes a wire being routed into the power receiver coil and uniformly spaced between adjacent turns, two terminals extending from the power receiver coil, and a base on which the power receiver coil is placed.

14. The system of claim 13, wherein each of the one of more power receiver coils has a coil type of a flexible printed circuit board.

15. The system of claim 13, wherein each of the one or more power receiver coils has a circular shape.

16. The system of claim 13, wherein each of the one or more power receiver coils has an outer diameter of 48-52 mm.

17. The system of claim 13, wherein each of the one or more power receiver coils has an inner diameter of 23-27 mm.

18. The system of claim 13, wherein each of the one or more power receiver coils has 11-13 turns.

19. The system of claim 13, wherein the wire is uniformly spaced between adjacent turns with an edge-to-edge spacing of 0.3-0.5 mm.

20. The system of claim 13, wherein the wire is made of copper, and has a trace thickness of 1.5-2.5 oz. and a trace width of 0.515-0.835 mm.

21. The system of claim 13, wherein the two terminals are separated with an edge-to-edge distance of 1 mm.

22. The system of claim 13, wherein the two terminals are bent to form an angle of 45°.

23. The system of claim 13, wherein the base is a dielectric material.

24. The system of claim 13, wherein the base is made of polyimide, and has a thickness of 0.025 mm.
